(19) United States
(12) Patent Application Publication
(10) Pub. No.: US 2024/0028783 A1
(43) Pub. Date: Jan. 25, 2024

(54) AUTOMATED DESIGN OF ARCHITECTURAL STRUCTURES FOR FABRICATION WITH STANDARD COMPONENTS

(71) Applicant: AUTODESK, INC., San Francisco, CA (US)

(72) Inventors: Rui WANG, New York City, NY (US); David BENJAMIN, Brooklyn, NY (US); Pradeep Kumar JAYARAMAN, Toronto (CA); Nigel Jed Wesley MORRIS, Toronto (CA)

(21) Appl. No.: 17/894,978

(22) Filed: Aug. 24, 2022

Related U.S. Application Data
(60) Provisional application No. 63/391,203, filed on Jul. 21, 2022.

(51) Int. Cl. G06F 30/13

(52) U.S. Cl. CPC G06F 30/13

(57) ABSTRACT

A generative design system includes a solver and a modeling tool comprising a visual programming interface and a design workflow script. The visual programming interface enables the user to specify a design problem including design constraints comprising parameters associated with standard building components, such as beams and joints. After the design problem is specified by the user, the modeling tool executes the design workflow script to automatically perform a design workflow that generates a design solution for the design problem. The design workflow script controls the operations of the modeling tool and the solver to interact in a collaborative manner to execute the design workflow comprising an ordered sequence of operations. The design solution comprises a 3D model of a modular beam structure that can be easily fabricated using standard building components, such as standardized beams and joints.

### CROSS-REFERENCE TO RELATED APPLICATIONS

This application claims the priority benefit of the United States Provisional patent application titled, “AUTOMATED DESIGN OF ARCHITECTURAL STRUCTURES FOR FABRICATION WITH STANDARD COMPONENTS,” filed on Jul. 21, 2022 and having Ser. No. 63/391,203. The subject matter of this related application is hereby incorporated herein by reference.

### BACKGROUND

### Field of the Various Embodiments

The various embodiments relate generally to computer science and computer-aided design software and, more specifically, to automated design of architectural structures for fabrication with standard components.

### Description of the Related Art

Designers, such as designers of small and medium scale objects, oftentimes use computer-aided design (CAD) systems to assist in developing design solutions to design problems. In particular, CAD systems provide various design tools, such as modeling tools and topology optimization solvers, to assist in generating design solutions that satisfy/fulfill objectives and constraints specified in the design problems. Conventional design tools typically generate design solutions comprising “organic” geometric shapes that are continuous and non-modular in form. For a given design solution, a digital fabrication process, such as three-dimensional (3D) printing or computer numerical control (CNC), is then used to produce a physical product based on the design solution that fulfills the associated design problem.

One drawback of the above design approach is that the generated design solutions that comprise architectural-scale structures, such as buildings, houses, and pavilions intended to be occupied by humans, oftentimes cannot be fabricated easily, if at all. In that regard, a more typical design solution that includes a continuous non-modular shape for a small-scale product normally can be readily fabricated using a standard digital fabrication process, such as 3D printing or CNC. By contrast, a continuous shape for a large-scale architectural structure cannot be fabricated using standard digital fabrication processes. Rather, architectural-scale structures are most easily fabricated using standard modular building components, such as beams and joints. Generative CAD design systems can be implemented to generate designs for architectural-scale structures. However, conventional generative design tools are not effective at generating design solutions that include geometric shapes corresponding to standard modular building components.

Another drawback of the above design approach is that conventional CAD systems are not capable integrating functions of the various design tools to generate a design solution for an architectural structure resulting in a manually-intensive process for a designer. For example, the designer usually has to program/code the design problem into a topology optimization solver, manually initiate design algorithms of the topology optimization solver and other design tools, and transfer data between the topology optimization solver and other design tools to generate a design solution for the design problem. Also, to perform additional iterations of the design process to generate different design solutions for different design problems, a designer also has to modify the design problem manually and repeat all of above steps and manually perform the above steps of the design process for each iteration. Consequently, the overall design space cannot be properly explored, resulting in suboptimized design solutions.

As the foregoing illustrates, what is needed in the art are more effective techniques for generating and rationalizing design solutions for architectural-scale structures.

### SUMMARY

Various embodiments include a computer-implemented method for generating a design for an architectural structure. The computer-implemented method includes receiving a design problem. The computer-implemented method also includes automatically executing a design workflow by: generating a design problem specification based on the design problem, generating an optimized mesh geometry based on the design problem specification, generating a graph structure based on the optimized mesh geometry, and generating a three-dimensional (3D) model based on the graph structure.

At least one technical advantage of the disclosed techniques relative to the prior art is that the disclosed techniques provide a parametric modeling tool that includes a visual programming interface through which design constraints can be defined that specify parameters that correspond to standard modular building components. For example, the design constraints can include parameters corresponding to a standard beam and/or standard joint. Further, the visual programming interface enables designers to easily define design constraints for design problems without having programming/coding expertise or knowledge. Another technical advantage is that, with the disclosed techniques, the design solutions generated for given design problems include geometric shapes that correspond to standard building components. Consequently, design solutions for architectural-scale structures can be readily fabricated and assembled using standard building components. An additional technical advantage of the disclosed techniques relative to the prior art is that the parametric modeling tool is configured to integrate various functions of the parametric modeling tool and the topology optimization solver to automatically execute an overall design workflow to generate a design solution for a given design problem. In this regard, the parametric modeling tool executes a design workflow script that causes the parametric modeling tool and a topology optimization solver to interact in a collaborative manner to execute the design workflow. Notably, the design workflow script is configured to automatically cause multiple iterations of the design workflow to be executed. More specifically, for each iteration, the design workflow script automatically modifies the design problem and causes the design workflow to be re-executed based on the modified design problem. In this manner, the parametric modeling tool integrates functions of the parametric modeling tool and the topology optimization solver to automatically execute iterations of an overall design workflow to generate multiple design solutions for multiple design problems, thus allowing a designer to fully explore the overall design space. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 illustrates a design system configured to implement one or more aspects of the various embodiments.

FIG. 2 is a more detailed illustration of the interactions between the different components of the design system of FIG. 1 when executing a design workflow, according to various embodiments.

FIG. 3 illustrates an exemplar mesh geometry included in the design problem specification of FIG. 2, according to various embodiments.

FIG. 4 illustrates an exemplar optimized mesh geometry generated based on the mesh geometry of FIG. 3, according to various embodiments.

FIG. 5 illustrates an exemplar graph structure generated based on the optimized mesh geometry of FIG. 4, according to various embodiments.

FIG. 6 illustrates an exemplar 3D model generated based on the graph structure of FIG. 5, according to various embodiments.

FIG. 7 illustrates an exemplar user screen provided by the visual programming interface of FIG. 2, according to various embodiments.

FIG. 8 sets forth a flow diagram of method steps for automatically executing a design workflow, according to various embodiments.

### DETAILED DESCRIPTION

In the following description, numerous specific details are set forth to provide a more thorough understanding of the various embodiments. However, it will be apparent to one skilled in the art that the inventive concepts may be practiced without one or more of these specific details. For explanatory purposes, multiple instances of like objects are denoted with reference numbers identifying the object and parenthetical alphanumeric character(s) identifying the instance where needed.

### Overview

Generative design systems include hardware and software components that operate to generate a three-dimensional (3D) design solution that satisfies/fulfills a design problem provided by a designer/user. In some embodiments, the generative design system includes a topology optimization solver (“solver”) and a parametric modeling tool (“modeling tool”) comprising an integrated visual programming interface and a design workflow script. The visual programming interface enables the user to specify a design problem comprising design objectives and design constraints. With respect to the design constraints, the visual programming interface enables the user to specify constraints comprising parameters corresponding to standard building components, such as beams and joints. In some embodiments, the constraints include a set of beam parameters specifying one or more size dimensions of a beam component and/or a set of joint parameters specifying one or more size dimensions of a joint component. For example, the constraints can include beam parameters specifying a thickness and width of the beams (such as 2″×4″ beams). Advantageously, the visual programming interface enables the user to easily specify design constraints without requiring programming of the design constraints via coding or program scripts.

After the design problem for the architectural structure is specified by the user, the modeling tool executes the design workflow script to automatically perform a design workflow that generates a design solution for the design problem. The design solution comprises a 3D model of a modular beam structure that can be easily fabricated using standard building components, such as standardized beams and joints. In some embodiments, after the user specifies and enters the design problem, the modeling tool (via execution of the design workflow script) can automatically execute the design workflow to generate the design solution without requiring further human intervention or human interaction. In further embodiments, the modeling tool also automatically performs additional iterations of the design workflow by automatically adjusting/changing the design constraints and re-executing the design workflow at each iteration. In these embodiments, after the user specifies the design problem and a set of iteration parameters, the modeling tool (via execution of the design workflow script) can automatically perform multiple iterations of the design workflow to generate multiple different design problems and multiple different design solutions without requiring further human intervention or human interaction.

In particular, the design workflow script executed by the modeling tool is configured to control the operations of the modeling tool and the solver to interact in a collaborative manner to perform an ordered sequence of operations. In these embodiments, the generative design workflow comprises the ordered sequence of operations that is performed between the modeling tool and the solver. In this regard, the design workflow begins when the modeling tool receives an entered design problem (including design constraints) from the user via the visual programming interface. In response to the entered design problem, the modeling tool executes the design workflow script which initiates the modeling tool to generate a design problem specification based on the current design problem. The design problem specification can include a mesh geometry and a text file that in combination represents and describes the design problem. The design workflow script then causes the modeling tool to output the design problem specification to the solver, and initiates the solver to execute a topology optimization algorithm for generating an optimized mesh geometry based on the design problem specification. The design workflow script then initiates the solver to execute a graph extraction algorithm for generating a graph structure based on the optimized mesh geometry. The graph structure comprises interconnected beams/edges and joints/nodes that represent the optimized mesh geometry in a modular graph form. The design workflow script then causes the solver to output the graph structure to the modeling tool, and initiates the modeling tool to perform a 3D modeling algorithm for generating a final 3D model based on the graph structure. The final 3D model includes final 3D locations and geometries (sizes and shapes) for the beams and joints and comprises a design solution for the architectural structure that satisfies the design problem. The final 3D model can then be easily specified and then fabricated using standard beams and joints.

In further embodiments, when entering the design problem via the visual programming interface, the user can also specify various iteration parameters used to control/configure multiple iterations of the design workflow. In some embodiments, the iteration parameters include a range of values for a particular constraint, an adjustment amount for the range of values for a particular constraint that is applied in different iterations of the design workflow, and/or a total number of iterations for the design workflow. For example, the user can specify a range of thickness values for a beam, adjustment amounts for the range of thickness values for a beam, a range of width values for a beam, adjustment amounts for the range of width values for a beam, a range of 3D locations for an object geometry, and an adjustment amount for the range of 3D locations for the object geometry. In these embodiments, after the first iteration of the design workflow is performed, the design workflow script causes the modeling tool and solver to automatically perform additional iterations of the design workflow based on the iteration parameters. In particular, the design workflow script causes the modeling tool to automatically modify the design problem by adjusting/changing one or more design constraints based on the iteration parameters to generate a new design problem. The design workflow script then causes the modeling tool and solver to automatically re-execute the design workflow based on the new design problem to generate a new design solution that satisfies the new design problem. In this manner, the design workflow script executed by the modeling tool can cause the modeling tool and solver to automatically perform multiple iterations of the design workflow to generate multiple different design problems and multiple different design solutions without requiring further manual operations by the user (other than the user specifying the design problem and the set of iteration parameters).

### Design System

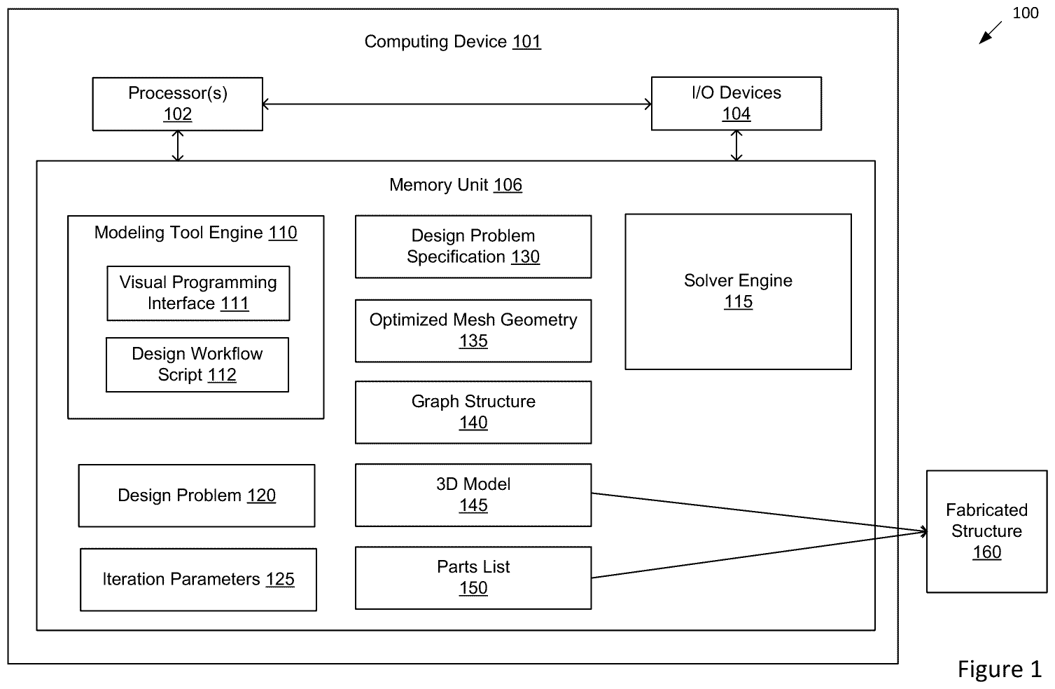

FIG. 1 illustrates a design system 100 configured to implement one or more aspects of the various embodiments. The design system 100 includes a computing device 101 and a fabricated structure 160. The computing device 101 comprises one or more processors 102 coupled to input/output (I/O) devices 104 and to a memory 106.

The computing device 101 can comprise a server, personal computer, laptop or tablet computer, mobile computing device, or any other device suitable for practicing various embodiments described herein. Further, the computing elements shown in computing device 101 can correspond to a physical computing system (e.g., a system in a data center) or can be a virtual computing instance executing within a computing cloud. Processor 102 can be a central processor (CPU), a graphics processor (GPU), an application-specific integrated circuit (ASIC), a field-programmable gate array (FPGA), and so forth. Processor 102 can also be a combination of different processors, such as a CPU configured to operate in conjunction with a GPU, or many CPUs configured to work together through cloud computing. In general, processor 102 can be any technically feasible form of processing device configured to process data and execute program code. The processor 102 executes software and performs one or more of the functions and operations described herein.

I/O devices 104 are also coupled to memory 106 and can include devices capable of receiving input, such as a keyboard, a mouse, a trackball, and so forth, as well as devices capable of providing output, such as a display, speaker, and so forth. Additionally, I/O devices can include devices capable of both receiving input and providing output, such as a touchscreen, a universal serial bus (USB) port, and so forth. I/O devices 104 can be configured to receive various types of input from an end-user of the design system 100, and to also provide various types of output to the end-user of design system 100. I/O devices 104 can also include a network card configured to couple computing device 101 to a network (not shown). A network is any technically feasible type of communications network that allows data to be exchanged between computing device 101 and external entities or devices, such as a web server or another networked computing device. For example, the network could include a wide area network (WAN), a local area network (LAN), a wireless (WiFi) network, and/or the Internet, among others.

Memory 106 is configured to store data and can include non-volatile storage (such as a hard disk), a random access memory (RAM) module, a flash memory unit, or any other type of memory unit or combination thereof. Processor 102 and I/O devices 104 are configured to read data from and write data to memory 106. Memory 106 includes various software programs that can be executed by processor(s) 102 and application data associated with said software programs. As shown, memory 106 includes a parametric modeling tool engine (“modeling tool engine”) 110, a topology optimization solver engine (“solver engine”) 115, design problem 120, a set of iteration parameters 125, a design problem specification 130, an optimized mesh geometry 135, a graph structure 140, a 3D model 145, and a parts list 150. The modeling tool engine 110 includes an integrated visual programming interface 111 and a design workflow script 112.

### Generative Design Workflow

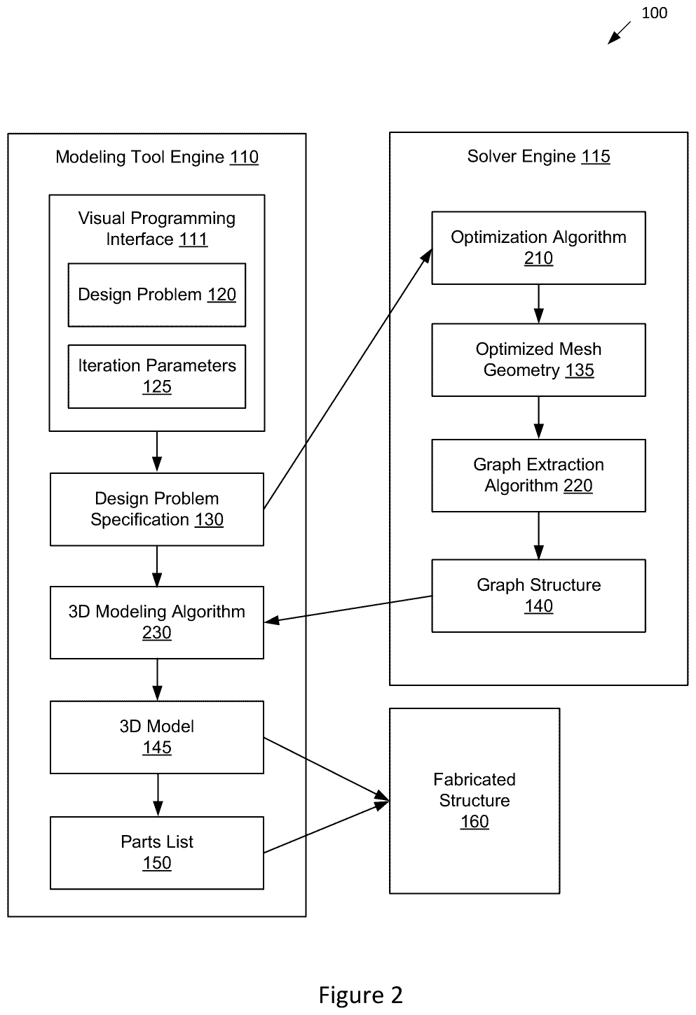

FIG. 2 is a more detailed illustration of the interactions between the different components of the design system of FIG. 1 when executing a design workflow, according to various embodiments. A designer/user interacts with the visual programming interface 111 of the modeling tool engine 110 to specify a design problem 120 (including design objectives and design constraints) and a set of iteration parameters 125. In response to the user submitting/entering the design problem 120 and/or the set of iteration parameters 125, the modeling tool engine 110 executes the design workflow script 112 that automatically initiates/causes the modeling tool engine 110 and the solver engine 115 to perform the generative design workflow illustrated in FIG. 2. As shown, the generative design workflow comprises an ordered sequence of operations that is performed between the modeling tool engine 110 and the solver engine 115.

In particular, in response to the user submitting/entering the design problem 120 and/or the set of iteration parameters 125, the design workflow script 112 initiates the modeling tool engine 110 to generate a design problem specification 130 based on the entered design problem 120. The design problem specification 130 can include a mesh geometry and a text file that represents and describes the design problem 120. The design workflow script 112 then causes the modeling tool engine 110 to output the design problem specification 130 to the solver engine 115.

The design workflow script 112 then initiates the solver engine 115 to execute a topology optimization algorithm 210 for generating an optimized mesh geometry 135 based on the design problem specification 130. The design workflow script 112 then initiates the solver engine 115 to execute a graph extraction algorithm 220 for generating a graph structure 140 based on the optimized mesh geometry 135. The graph structure 140 comprises a plurality of joints/nodes that are interconnected by a plurality of beams/edges that represent the optimized mesh geometry 135 in a modular graph form. The optimized mesh geometry 135 and graph structure 135 each satisfy the design objectives and design constraints specified in the design problem 120 and the design problem specification 130. The design workflow script 112 then causes the solver engine 115 to output the graph structure 140 to the modeling tool engine 110.

The design workflow script 112 then initiates the modeling tool engine 110 to perform a 3D modeling algorithm 230 to generate a final 3D model 145 based on the graph structure 140 and the design problem specification 130. The final 3D model 145 includes final 3D locations and geometries (sizes and shapes) for the beams and joints and comprises a design solution that satisfies the design problem 120 and the design problem specification 130. In further embodiments, the design workflow script 112 then initiates the modeling tool engine 110 to generate a parts list 150 based on the 3D model 145. In some embodiments, the 3D model 145 comprises a design of a large-scale architectural structure to be fabricated with standard building components. The parts list 150 comprises a list of building components (such as beams and joints) needed to fabricate/construct the architectural structure.

After the 3D model 145 is generated, the design workflow script 112 can then cause additional iterations of the design workflow to be automatically performed based on the set of iterations parameters 125. Multiple iterations of the design workflow can be performed to generate different design problems 120 and different design solutions (3D models 145) for the different design problems 120. After multiple different design solutions (3D models 145) are generated, the designer/user can select a particular design solution (a particular 3D model 145) for fabrication. The parts list 150 corresponding to the selected 3D model 145 can be submitted to a manufacturer of such building components.

The selected 3D model 145 and the parts list 150 are then used to physically assemble the fabricated architectural structure 160 using standard building components. An architectural structure comprises a large-scale structure intended to contain and be occupied by humans, such as various room-sized structures, buildings, houses, pavilions, stadiums, terminals, and the like. Standardized building components are the best option for building/fabricating such large architectural-scale structures. Standard building components can comprise segmented/modular components with predetermined standardized shapes and/or sizes (such as 2″×4″ beams) that are typically used by construction companies. Such standardized modular components are easily available and allow for efficient assembly and disassembly of architectural-scale structures.

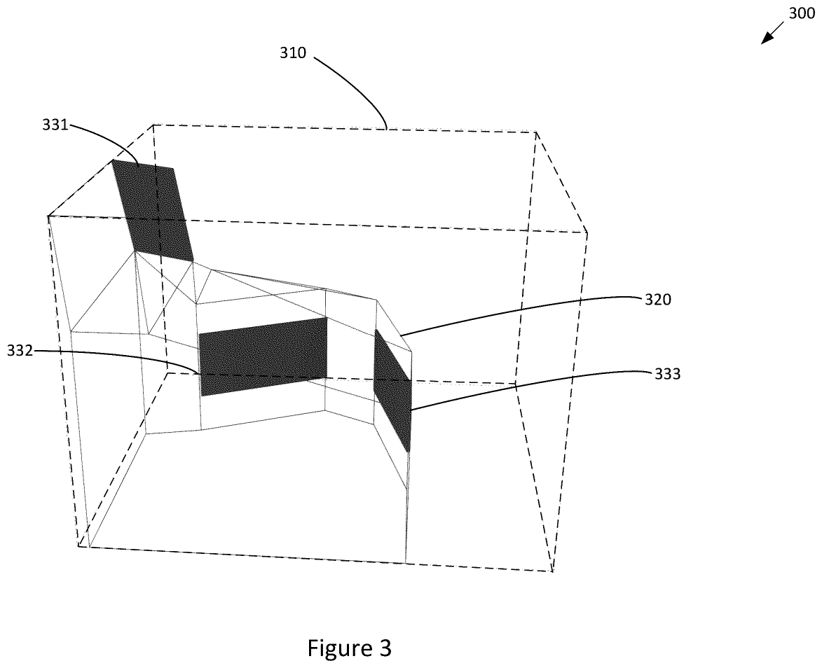

FIG. 3 illustrates an exemplar mesh geometry 300 included in the design problem specification 130 of FIG. 2, according to various embodiments. As discussed above, the design workflow script 112 initiates the modeling tool engine 110 to generate a design problem specification 130 based on the design problem 120. The design problem 120 includes a set of design objectives and a set of design constraints for designing an architectural structure. The design solution for the architectural structure that is generated by the design workflow should satisfy the set of design objectives and set of design constraints of the design problem 120. A design objective can specify a property in the design solution to be optimized (maximized or minimized), such as maximizing stiffness, minimizing displacement, or minimizing weight, volume, or footprint, while still satisfying the design constraints. A design constraint can specify a value of a property or parameter of the design solution that the design solution cannot violate and must satisfy.

The set of design constraints includes a set of geometric constraints and a set of load constraints (boundary conditions). The geometric constraints include a bounding volume, an obstacle volume, one or more object geometries, a volume fraction target, material properties, beam parameters, and/or joint parameters. The volume fraction target constraint can comprise a real number between 0 to 1 that specifies the fraction of the initial design space that should be filled with material (vs empty space). The volume fraction target constraint can guide the algorithm to achieve a particular density of structure and can be tuned by the user to achieve a desired result. A bounding volume comprises a geometry that defines a volume where components/material of the architectural structure can exist, excluding the obstacle volume. An obstacle volume comprises a geometry that defines a volume where components/material of the architectural structure cannot exist, such as an area designated for people to occupy. Therefore, an obstacle volume defines “keep-out-zones” where beam and joint components of the architectural structure cannot be placed. Each object geometry defines an area or volume where an object is to be placed on or within the architectural structure. Each object geometry also defines the geometry upon which load constraints (boundary conditions) are applied. For example, an object geometry can represent a display screen that is to be located on or within the architectural structure and can specify the display screen size and 3D location within the architectural structure.

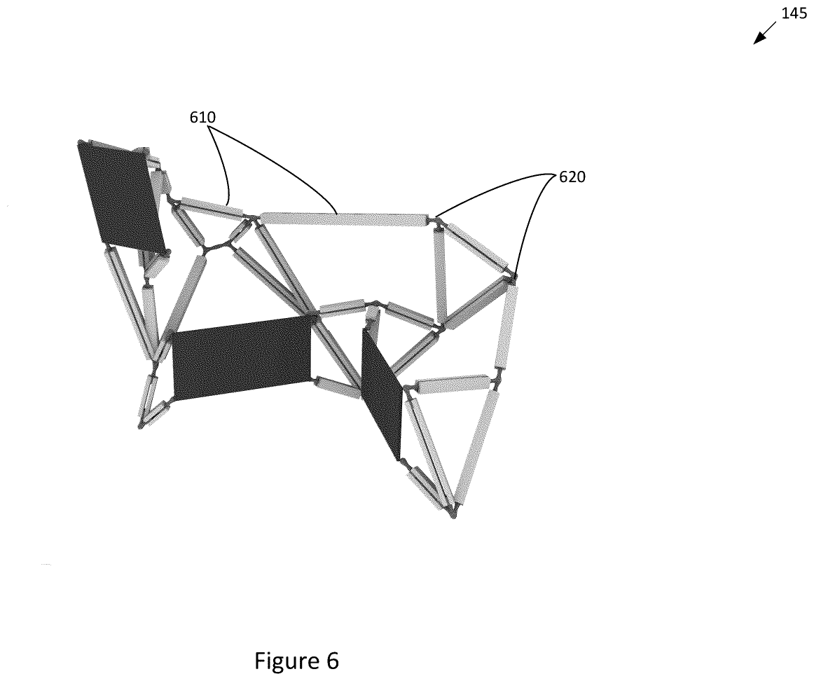

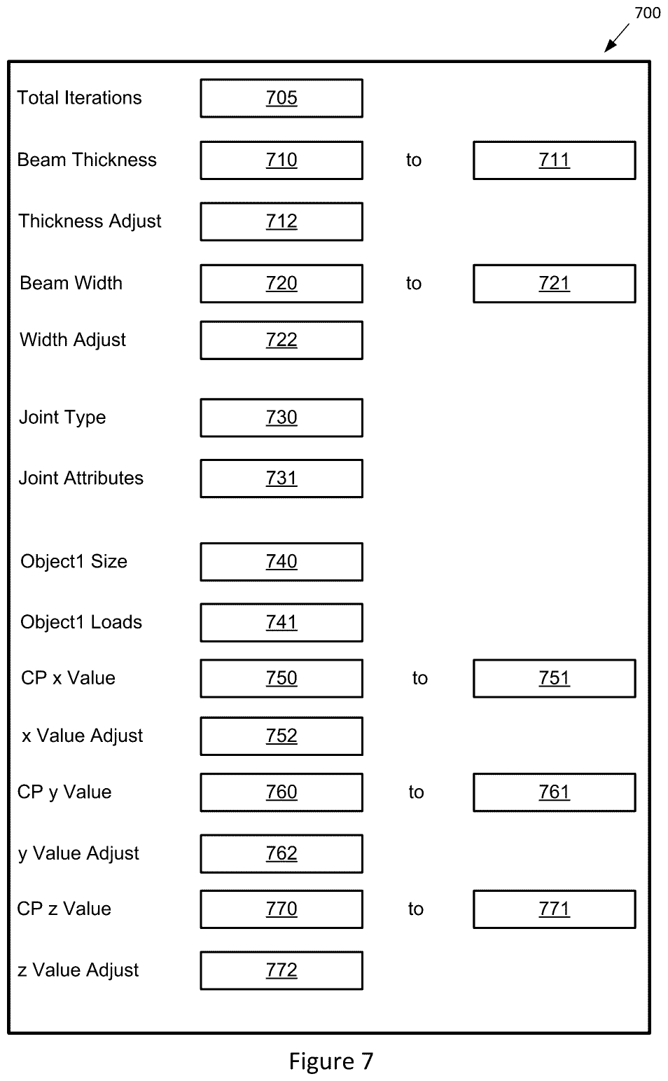

The material properties define properties of the components of the architectural structure, such as Youngs Modulus, Poisson ratio, and the like. The geometric constraints further include parameters associated with standard building components, such as beam parameters and joint parameters. Beam parameters can specify a thickness and/or width of the beams (such as 2″×4″ beams). The joint parameters can specify the type of joint (such as a modular spaceframe joint), radius of the center sphere, and a diameter of the spokes. Beam and joint parameters are discussed below in relation to FIGS. 6-7.

The set of design constraints also includes a set of load constraints. The set of load constraints specifies locations where loads appear on the architectural structure and the force values (such as newtons of force) of those loads. Thus, the load constraints define forces that the design solution for the architectural structure must tolerate in a real-world environment.

In some embodiments, the modeling tool engine 110 comprises a parametric modeling tool capable of specifying geometric constraints via a mesh geometry 300. In this regard, the design problem specification 130 can include a mesh geometry 300 and a text file that in combination represents and describes the design problem 120. The mesh geometry 300 can include 3D geometries that visually illustrate and represent one or more geometric constraints specified in the design problem 120. For example, the mesh geometry can comprise a Standard Triangle Language (STL) mesh geometry.

As shown in the example of FIG. 3, the mesh geometry 300 includes a bounding volume 310, an obstacle volume 320, a first object geometry 331, a second object geometry 332, and a third object geometry 333. The bounding volume 310 is indicated by dashed lines, and the obstacle volume 320 is indicated by solid lines. The obstacle volume 320 indicates a volume where components of the architectural structure cannot be placed/exist. The volume resulting from removing the obstacle volume 320 from the bounding volume 310 indicates the volume where components of the architectural structure can be placed/exist.

The first object geometry 331 is indicated by a first shaded area. The first object geometry 331 defines an area or volume where a first display screen is to be placed within the architectural structure. The design problem 120 also specifies load constraints at each corner of the first object geometry 331 (such as the locations and load values at each corner of the first object geometry 331). The second object geometry 332 is indicated by a second shaded area. The second object geometry 332 defines an area or volume where a second display screen is to be placed within the architectural structure. The design problem 120 also specifies load constraints at each corner of the second object geometry 332 (such as the locations and load values at each corner of the second object geometry 332). The third object geometry 333 is indicated by a third shaded area. The third object geometry 333 defines an area or volume where a third display screen is to be placed within the architectural structure. The design problem 120 also specifies load constraints at each corner of the third object geometry 333 (such as the locations and load values at each corner of the third object geometry 333).

The remaining design constraints specified in the design problem 120 that are not represented in the mesh geometry 300 are included in the text file. For example, the material properties, beam parameters, joint parameters, and load constraints can be specified in the text file. The text file can further include the design objectives specified in the design problem 120. For example, the text file can comprise a JavaScript Object Notation (JSON) file.

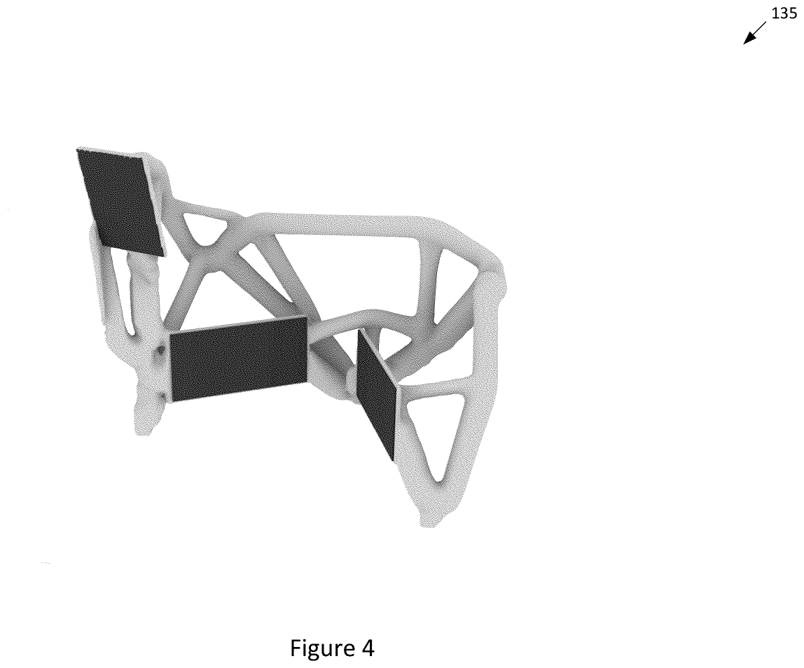

FIG. 4 illustrates an exemplar optimized mesh geometry generated based on the mesh geometry of FIG. 3, according to various embodiments. As discussed above, the design workflow script 112 initiates the solver engine 115 to execute a topology optimization algorithm 210 for generating an optimized mesh geometry 135 based on the design problem specification 130. As shown, the optimized mesh geometry 135 includes a beam-like structure that satisfies the design problem specification 130. For example, the optimized mesh geometry 135 can comprise a Standard Triangle Language (STL) mesh geometry.

In some embodiments, the topology optimization algorithm 210 implements a level set-based structural topology optimization routine with an Augmented Lagrangian (AL) optimization framework composed of the objective being the compliance of the structure and a set of geometric constraints, each with Lagrange multipliers and penalty parameters. For example, the set of constraints can include a volume fraction target constraint and a maximum beam thickness constraint. In some embodiments, the set of constraints can include a volume fraction target constraint, a beam thickness constraint specifying a single value, and a beam width constraint specifying a single value. To solve the AL problem, the topology optimization algorithm 210 solves the unconstrained optimization problem to convergence with the fixed Lagrange multipliers and penalty parameters and then iteratively/repeatedly updates the fixed Lagrange multipliers and penalty parameters until the set of constraints are satisfied. The optimized mesh geometry is first initialized as a block of material surrounding the input mesh geometry, and at each iteration the shape of the optimized mesh geometry is advected by the shape derivative of the Lagrangian. The resulting optimized mesh geometry 135 comprises a representation of the optimized level-set produced by the optimization algorithm 210. In other embodiments, the topology optimization algorithm 210 implements any other type of topology optimization technique for generating the optimized mesh geometry 135 based on the design problem specification 130.

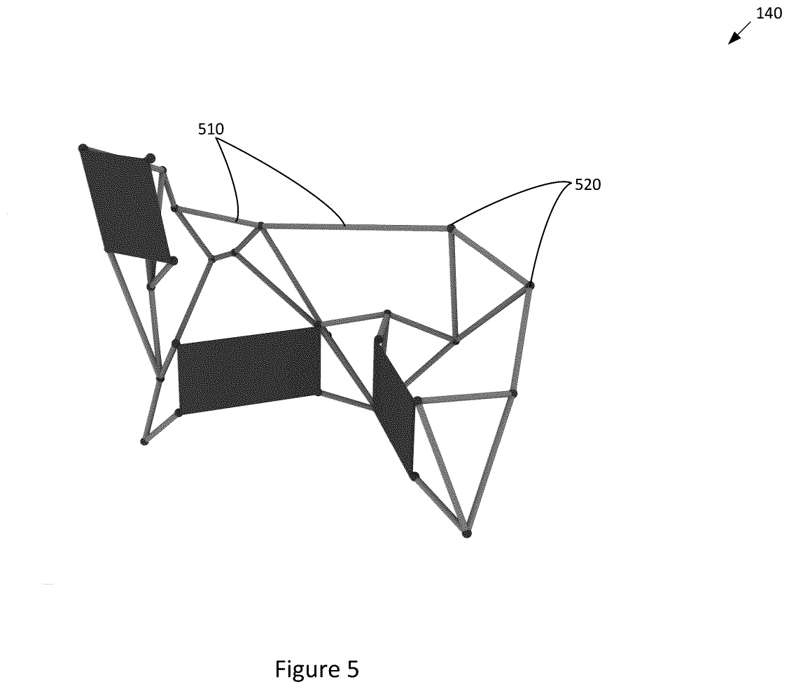

FIG. 5 illustrates an exemplar graph structure 140 generated based on the optimized mesh geometry 135 of FIG. 4, according to various embodiments. As discussed above, the design workflow script 112 initiates the solver engine 115 to execute a graph extraction algorithm 220 for generating a graph structure 140 based on the optimized mesh geometry 135.

As shown, the graph structure 140 includes a graph network comprising a plurality of joints/nodes 520 that are interconnected by a plurality of beams/edges 510 that represent the optimized mesh geometry 135 in a modular graph form. Note that the graph structure 140 indicates the 3D locations of the joints/nodes 520, and the 3D locations and lengths of the beams/edges 510. The graph structure 140 also indicates, for each joint/node 520, the number of beams/edges 510 connected to the joint/node 520 and the angle of each connected beam/edge 510. Each joint/node 520 can connect two or more beams/edges 510. The number of beams/edges 510 connected to the joint/node 520 defines the number of spokes of the joint/node 520, each spoke corresponding to a particular connected beam/edge 510. The angle of each connected beam/edge 510 defines the angle of the corresponding spoke. The number of spokes of the joint/node 520 and the angles of the spokes are discussed below in relation to FIG. 6.

In some embodiments, the graph extraction algorithm 220 implements a robust skeleton method (such as a 3D medial surface axis thinning algorithm) to extract the medial axis of the optimized level-set geometry of the optimized mesh geometry 135 to build a skeleton model. The graph extraction algorithm 220 then identifies endpoints and junctions in the skeleton model as nodes and the lines that match the topology of the skeleton model between the nodes as the edges. In other embodiments, the graph extraction algorithm 220 implements any other type of graph extraction technique for generating the graph structure 140 based on the optimized mesh geometry 135.

In some embodiments, the graph structure 140 can be represented as two lists: a first list of joints/nodes and a second list of beams/edges. The first list of joints/nodes specifies, for each joint/node in the graph structure 140, a unique identifier for the joint/node and 3D coordinates (x, y, z coordinates) that specify the 3D location of the joint/node within the graph structure 140. The second list of beams/edges specifies each beam/edge in the graph structure 140 as a vector from a first joint/node to a second joint/node in the graph structure 140. In this manner, the specified vectors are interconnected to form the graph structure 140. In these embodiments, the graph structure 140 is represented by the two lists in a text file (such as a JSON file) that is output to the modeling tool engine 110 for processing by the 3D modeling algorithm 230 to generate the final 3D model 145.

FIG. 6 illustrates an exemplar 3D model 145 generated based on the graph structure 140 of FIG. 5, according to various embodiments. As discussed above, the design workflow script 112 initiates the modeling tool engine 110 to perform a 3D modeling algorithm 230 to generate a final 3D model 145 of the architectural structure based on the graph structure 140 and the design problem specification 130.

As shown, the 3D model 145 comprises a modular beam structure comprising a plurality of joints 620 that are interconnected by a plurality of beams 610. The final 3D model 145 includes final 3D locations and geometries (sizes and shapes) for the beams 610 and joints 620. In some embodiments, the 3D modeling algorithm 230 determines the overall configuration and shape of the architectural structure (the 3D locations of the beams and joints) based on the graph structure 140, and determines the final geometries (sizes and shapes) for the beams 610 and joints 620 based on the graph structure 140 and the design problem specification 130 to generate the final 3D model 145.

For each joint of the architectural structure, the 3D modeling algorithm 230 can determine the 3D location of the joint based on the graph structure 140. The 3D modeling algorithm 230 can then determine the size and shape of each joint based on the design problem specification 130 and the graph structure 140. For example, a current type of joint being implemented can comprise a modular spaceframe joint comprising a center sphere in the middle and two or more spokes that connect the center sphere to two or more end plates connected to support two or more beams. Note that in these embodiments, the beam design for each beam includes an interlocking metal plate at each end of the beam. The design problem specification 130 can include joint parameters including the type of joint (such as a modular spaceframe joint), radius of the center sphere, and a diameter of the spokes. For each joint, the 3D modeling algorithm 230 can determine the number of spokes (two or more) and the angle of each spoke based on the graph structure 140.

For each joint, the 3D modeling algorithm 230 can generate a 3D model of the joint at the joint location by implementing a geometric algorithm corresponding to the type of joint being implemented. For example, a first geometric algorithm can correspond to a first type of joint (such as a modular spaceframe joint), and a second geometric algorithm can correspond to a second type of joint. For each joint, the geometric algorithm is instantiated at the joint location to generate a 3D model of the joint based on the radius of the center sphere, the diameter of the spokes, the number of spokes, and the angle of each spoke of the joint. Thus, the 3D modeling algorithm 230 can generate realistic 3D geometries of the joints at the joint locations in the 3D model 145.

For each beam of the architectural structure connecting two joints, the 3D modeling algorithm 230 can determine the location and length of each beam based on the graph structure 140. The 3D modeling algorithm 230 can then determine the thickness and width of the beams based on the design problem specification 130, which can include beam parameters specifying a thickness and width of the beams (such as 2″×4″ beams). Thus, the 3D modeling algorithm 230 can determine the final geometries (length, thickness, and width) of each of beam of the architectural structure, and generate realistic 3D geometries of the beams in the 3D model 145.

The final 3D model 145 comprises a design solution that satisfies the design problem 120 and the design problem specification 130. The final 3D model 145 includes accurate (true-to-life) representations of the beam and joint geometries of the architectural structure. Therefore, the final 3D model 145 comprises a constructable representation of the architectural structure and the resulting fabricated architectural structure 160 can be built based on the final 3D model 145.

In some embodiments, the design workflow script 112 then initiates the modeling tool engine 110 to generate a parts list 150 based on the 3D model 145. The parts list 150 comprises a list of building components needed to fabricate/construct the architectural structure. In particular, the parts list 150 specifies the attributes of each of beam and each joint of the architectural structure. The attributes of each beam comprises the size (length, thickness, and width) of each required beam, which can be automatically derived based on an analysis of the 3D model 145. In other embodiments, the attributes of each beam can be derived from the graph structure 140 and the design problem specification 130 in a manner similar to the method used for generating the 3D geometries of the beams for generating the 3D model 145, as discussed above in relation to FIG. 6. The attributes of each joint comprises the radius of the center sphere, the diameter of the spokes, the number of spokes, and the angle of each spoke of the joint, which can be automatically derived based on an analysis of the 3D model 145. In other embodiments, the attributes of each joint can be derived from the graph structure 140 and the design problem specification 130 in a manner similar to the method used for generating the 3D geometries of the joints for generating the 3D model 145, as discussed above in relation to FIG. 6. The 3D model 145 and the parts list 150 can be used to physically assemble the fabricated architectural structure 160 using standard building components.

FIG. 7 illustrates an exemplar user screen 700 provided by the visual programming interface of FIG. 2, according to various embodiments. The visual programming interface 111 of the modeling tool engine 110 provides a visual interface for the user to define objectives and constraints of the design problem without requiring expertise of program coding as required in conventional techniques. In some embodiments, when entering the design problem via the visual programming interface, the user can also specify various iteration parameters used to control/configure multiple iterations of the design workflow. As shown, the user screen 700 of the visual programming interface displays a plurality of selectable data fields 705-772 for which to define various design constraints and iteration parameters. In some embodiments, the iteration parameters include a range of values for a particular constraint, an adjustment amount for the range of values for a particular constraint that is applied in different iterations of the design workflow, and/or a total number of iterations for the design workflow.

In the example of FIG. 7, the user screen 700 displays a data field 705 to enter a total number of iterations for the design workflow, a data field 710 to enter a minimum thickness of the beam (such as 1″), a data field 711 to enter a maximum thickness of the beam (such as 2″), and a data field 712 to enter a beam thickness adjustment amount for different iterations (such as 0.25″). When values are entered for data fields 710-712, the entered values define a discrete set of beam thickness values that are permitted for the beam thickness, which ranges from the minimum thickness 710 to the maximum thickness 711, with increments to the beam thickness value equal to the thickness adjustment amount 712. For example, the discrete set of thickness values can include 1″, 1.25″, 1.5″, 1.75″, and 2″. In alternative embodiments, the visual programming interface 111 enables the user to directly enter a discrete set of beam thickness values (such as 1″, 1.5″, 1.75″, and 2″). These beam thickness values can correspond to common standard beam thickness sizes.

The user screen 700 also displays a data field 720 to enter a minimum width of the beam (such as 4″), a data field 721 to enter a maximum width of the beam (such as 6″), a data field 722 to enter a beam width adjustment amount for different iterations (such as 0.5″). When values are entered for data fields 720-722, the entered values define a discrete set of beam width values that are permitted for the beam width, which ranges from the minimum width 720 to the maximum width 721, with increments to the width value equal to the width adjustment amount 722. For example, the discrete set of width values can include 4″, 4.5″, 5″, 5.5″, and 6″. In alternative embodiments, the visual programming interface 111 enables the user to directly enter a discrete set of beam width values (such as 4″, 5″, 5.5″, and 6″). These beam width values can correspond to common standard beam width sizes.

Data fields 705-722 comprise iteration parameters 125 that are used by the design workflow script 112 to configure and control multiple iterations of the design workflow. When the above data fields 705-722 are entered by the user, for the first iteration of the design workflow, the modeling tool engine 110 defines a beam thickness constraint by selecting a single value from the discrete set of beam thickness values, such as the minimum beam thickness value (such as 1″) or the maximum beam thickness value (such as 2″). For the first iteration of the design workflow, the modeling tool engine 110 also defines a beam width constraint by selecting a single value from the discrete set of beam width values, such as the minimum beam width value (such as 4″) or the maximum beam width value (such as 6″). The design problem 120 is defined by the beam thickness constraint (comprising a single value such as 1″) and the beam width constraint (comprising a single value such as 4″) along with other design constraints and design objectives. After the design problem 120 is defined and entered via the visual programming interface, the design workflow script 112 then causes the first iteration of the design workflow to be performed to generate a design solution (3D model 145) that satisfies the design problem 120.

At the next iteration of the design workflow, the design workflow script 112 can automatically modify/change the beam thickness constraint and/or the beam width constraint by selecting different values for the beam thickness constraint and/or the beam width constraint based on the iteration parameters 125 in data fields 710-722. In particular, the design workflow script 112 can select a different value for the beam thickness constraint from the discrete set of beam thickness values and/or select a different value for the beam width constraint from the discrete set of beam width values at each iteration. The design workflow script 112 can select a different value for the beam thickness constraint and/or a different value for the beam width constraint in a methodical non-random manner to ensure that different combinations of values for the beam thickness constraint and the beam width constraint are used at different iterations. For example, the values for the beam thickness constraint and the beam width constraint can be 1″×4″ for a first iteration, 1.25″×4″ for a second iteration, 1.5″×4″ for a third iteration, 1.75″×4″ for a fourth iteration, 2″×4″ for a fifth iteration, 1″×4.5″ for a sixth iteration, and so forth.

In this manner, at each iteration, the design workflow script 112 automatically generates a different design problem 120 (having one or more different beam constraints) and automatically performs the design workflow to generate a different design solution for the different design problem 120. The design workflow script 112 can repeat the iterations until the total number of iterations 705 is reached. The user can then select a particular design solution among the plurality of different design solutions for physical fabrication.

In the above embodiments, the beams can comprise wood beams of standard sizes, such as 1″×4″, 2″×4″, and the like. In other embodiments, the user can also specify, in addition to sizes of beams, a type of beam, such as round tubes (hollow), square tubes (hollow), or solid bar beams, and the like. In further embodiments, the beams can comprise round metal beams of standard sizes, such as 1″, 1.25″, 1.5″, and the like. In these embodiments, the user screen 700 can display a data field to enter a minimum radius of the beam (such as 1″), a data field to enter a maximum radius of the beam (such as 2″), a data field to enter a beam radius adjustment amount applied at different iterations (such as 0.2″), which produces a discrete set of beam radius values (such as 1″, 1.25″, 1.5″, 1.75″, and 2″). A different beam constraint can then be used at each iteration by selecting a different beam radius from the discrete set of beam radius values at each iteration to generate a different design problem 120 and different design solution at each iteration. In alternative embodiments, the ranges of the beam thicknesses and widths are left variable within the ranges so that multiple sizes of beams can be recommended by the topology optimization.

In the example of FIG. 7, the user screen 700 also displays data fields for entering joint parameters, including a data field 730 to enter a joint type (such as a modular spaceframe joint) and a data field 731 to enter attributes of the joint type (such as a radius of the center sphere, and a diameter of the spokes). The joint attributes are specified by joint fabricators and are typically not modifiable. Joints from joint fabricators can comprise standard components or user-customized components.

In the example of FIG. 7, the user screen 700 also displays data fields for entering iteration parameters 125 for object geometry constraints. Each object geometry constraint comprises a geometric constraint that defines a volume where an object is to be placed on or within the architectural structure. Each object geometry also defines the geometry upon which load constraints (boundary conditions) are applied. For example, an object geometry can represent a display screen that is to be located on or within the architectural structure and can specify the display screen size and 3D location within the architectural structure.

As shown, the user screen 700 also displays data fields for defining constraints for a first object geometry of a first object (such as a first display screen), including a data field 740 for entering the object size/volume, and a data field 741 for entering load values at each corner of the first object. The object size/volume and load values can be dictated by the dimensions and loads of the object and are typically not modifiable.

The user screen 700 also displays a data field 750 to enter a minimum x location value of the object centerpoint (such as x1), a data field 751 to enter a maximum x location value of the object centerpoint (such as x2), and a data field 752 to enter an x location adjustment amount for each iteration (such as 3″). The data fields 750-752 define a discrete set of x values that are permitted for the x location of the object centerpoint from the minimum x location 750 to the maximum x location 751, with increments to the x location value equal to the x location adjustment amount 752. In alternative embodiments, the visual programming interface 111 enables the user to directly enter a discrete set of x values for the object centerpoint.

The user screen 700 also displays a data field 760 to enter a minimum y location value of the object centerpoint (such as y1), a data field 761 to enter a maximum y location value of the object centerpoint (such as y2), and a data field 762 to enter an y location adjustment amount for each iteration (such as 3″). The data fields 760-762 define a discrete set of y values that are permitted for the y location of the object centerpoint from the minimum y location 760 to the maximum y location 761, with increments to the y location value equal to the y location adjustment amount 762. In alternative embodiments, the visual programming interface 111 enables the user to directly enter a discrete set of y values for the object centerpoint.

The user screen 700 also displays a data field 770 to enter a minimum z location value of the object centerpoint (such as z1), a data field 771 to enter a maximum z location value of the object centerpoint (such as z2), and a data field 772 to enter an z location adjustment amount for each iteration (such as 3″). The data fields 770-772 define a discrete set of z values that are permitted for the z location of the object centerpoint from the minimum z location 770 to the maximum z location 771, with increments to the z location value equal to the z location adjustment amount 772. In alternative embodiments, the visual programming interface 111 enables the user to directly enter a discrete set of z values for the object centerpoint.

Data fields 705 and 750-772 comprise iteration parameters 125 that are used by the design workflow script 112 to configure and control multiple iterations of the design workflow. When the above data fields 705 and 750-772 are entered by the user, for the first iteration of the design workflow, the modeling tool engine 110 defines a first object geometry constraint by determining a 3D location of the first object centerpoint by selecting an x value from the discrete set of x values, selecting a y value from the discrete set of y values, and selecting a z value from the discrete set of z values. The first object geometry constraint can be further defined by the size/volume of the first object specified in data field 740. The combination of the 3D location of the first object centerpoint and the size/volume of the first object are used to fully define the first object geometry constraint. Load constraints can also be defined at each corner of the first object geometry based on the load values specified in data field 741.

At the next iteration of the design workflow, the design workflow script 112 can automatically modify/change the first object geometry constraint by changing the first object centerpoint based on the iteration parameters 125 in data fields 750-772. In particular, the design workflow script 112 can select a different x location of the object centerpoint from the discrete set of x values, select a different y location of the object centerpoint from the discrete set of y values, and/or select a different z location of the object centerpoint from the discrete set of z values at each iteration. The design workflow script 112 can select a different value for the x location, y location, and/or z location for the first object centerpoint in a methodical non-random manner to ensure that different combinations of x, y, and z values for the first object centerpoint are used at different iterations. Changes in the first object centerpoint will also cause corresponding changes to the load constraints at each corner of the first object at each iteration, in the sense that the location of the corner load constraints will move in a manner corresponding to the movement of the first object centerpoint. In this manner, at each iteration, the design workflow script 112 automatically generates a different design problem 120 (having different first object geometry constraints and corresponding load constraints) and automatically performs the design workflow to generate a different design solution for the different design problem 120. The design workflow script 112 can repeat the iterations until the total number of iterations 705 is reached.

In further embodiments, the user screen 700 also displays data fields for defining constraints for a second object geometry of a second object (such as a second display screen), and data fields for defining constraints for a third object geometry of a third object (such as a third display screen). The data fields for defining constraints for the second object geometry and the third object geometry would be similar to the data fields 740-772 for defining constraints for the first object geometry discussed above.

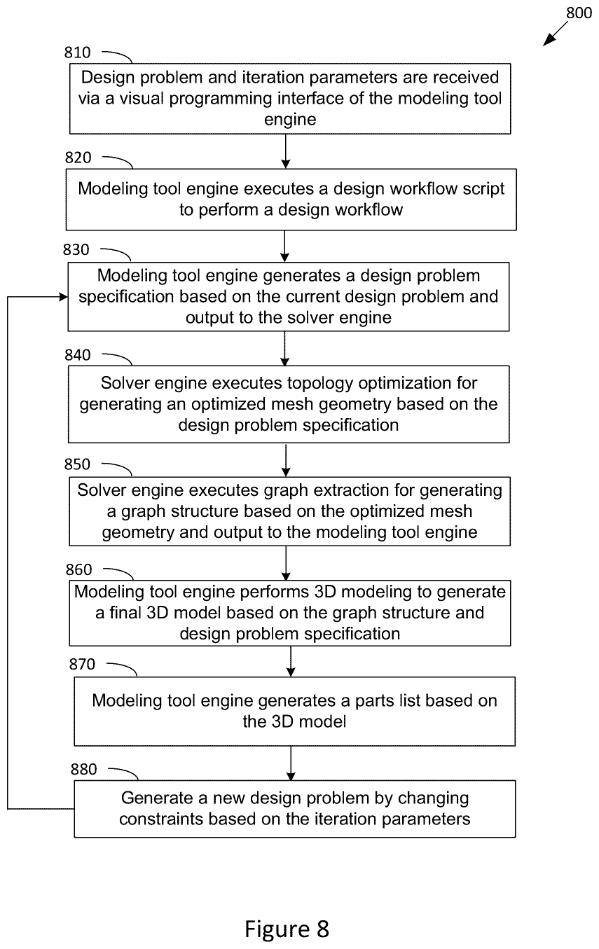

FIG. 8 sets forth a flow diagram of method steps for automatically executing a design workflow, according to various embodiments. Although the method steps are described with reference to the systems of FIGS. 1-7, persons skilled in the art will understand that any system configured to implement the method steps, in any order, falls within the scope of the disclosed embodiments. In some embodiments, the steps of the method 800 are performed by various components of the generative design system 100 such as the modeling tool engine 110 and the solver engine 115. In these embodiments, the design workflow script 112 integrates the functions of the modeling tool engine 110 and the solver engine 115 to perform the steps of the method 800.

As shown, a method 800 begins at step 810, where a user specifies a design problem 120 and a set of iteration parameters 125 via a visual programming interface 111 of the modeling tool engine 110. The design problem 120 includes design objectives and design constraints for an architectural structure to be designed. At step 820, in response to the user submitting/entering the design problem 120 and/or the set of iteration parameters 125, the modeling tool engine 110 executes the design workflow script 112 that automatically initiates/causes the modeling tool engine 110 and the solver engine 115 to operate in conjunction to iteratively perform steps 830-880 of the method 800. At step 830, the design workflow script 112 initiates/causes the modeling tool engine 110 to generate a design problem specification 130 (including a mesh geometry and a text file) based on the current design problem 120 and output the design problem specification 130 to the solver engine 115.

At step 840, the design workflow script 112 then initiates/causes the solver engine 115 to execute a topology optimization algorithm 210 for generating an optimized mesh geometry 135 based on the design problem specification 130. At step 850, the design workflow script 112 then initiates/causes the solver engine 115 to execute a graph extraction algorithm 220 for generating a graph structure 140 based on the optimized mesh geometry 135 and output the graph structure 140 to the modeling tool engine 110.

At step 860, the design workflow script 112 then initiates/causes the modeling tool engine 110 to perform a 3D modeling algorithm 230 to generate a final 3D model 145 of the architectural structure based on the graph structure 140 and the design problem specification 130. The final 3D model 145 includes final 3D locations and geometries (sizes and shapes) for the beams and joints of the architectural structure and comprises a design solution that satisfies the design problem 120. At step 870, the design workflow script 112 then initiates/causes the modeling tool engine 110 to generate a parts list 150 based on the 3D model 145. In other embodiments, the modeling tool engine 110 generates the parts list 150 based on the graph structure 140 and the design problem specification 130.

At step 880, the design workflow script 112 then automatically generates a different new design problem 120 by changing one or more design constraints based on the set of iteration parameters 125. The method 800 then returns to step 830 and re-performs steps 830-860 to generate a new design solution (new 3D model 145) that satisfies the new design problem 120. Steps 830-880 are repeated iteratively until the total number of iterations specified in the iteration parameters 125 is reached. The method 800 then ends. After multiple different design solutions (3D models 145) are generated, the designer/user selects a particular design solution (a particular 3D model 145) for fabrication. The parts list 150 corresponding to the selected 3D model 145 can be submitted to a manufacturer of such building components. The selected 3D model 145 and the parts list 150 are then used to physically assemble the fabricated architectural structure 160 using standard building components.

In sum, a generative design system includes a topology optimization solver (“solver”) and a parametric modeling tool (“modeling tool”) comprising a visual programming interface and a design workflow script. The visual programming interface enables the user to specify a design problem including design constraints comprising parameters associated with standard building components, such as beams and joints. After the design problem is specified by the user, the modeling tool executes the design workflow script to automatically perform a design workflow that generates a design solution for the design problem. The design solution comprises a 3D model of a modular beam structure that can be easily fabricated using standard building components, such as standardized beams and joints. The modeling tool (via execution of the design workflow script) can automatically execute the design workflow to generate the design solution without requiring further human intervention or human interaction. The modeling tool also automatically performs additional iterations of the design workflow by automatically adjusting/changing the design constraints and re-executing the design workflow at each iteration.

In particular, the design workflow script executed by the modeling tool is configured to control the operations of the modeling tool and the solver to interact in a collaborative manner to perform an ordered sequence of operations. The design workflow begins when the modeling tool receives an entered design problem (including design constraints) from the user via the visual programming interface. In response, the modeling tool executes the design workflow script which initiates the modeling tool to generate a design problem specification based on the entered design problem. The design problem specification can include a mesh geometry and a text file that in combination represents and describes the design problem. The design workflow script then causes the modeling tool to output the design problem specification to the solver, and initiates the solver to execute a topology optimization algorithm for generating an optimized mesh geometry based on the design problem specification. The design workflow script then initiates the solver to execute a graph extraction algorithm for generating a graph structure based on the optimized mesh geometry. The graph structure represents the optimized mesh geometry in a modular graph form. The design workflow script then causes the solver to output the graph structure to the modeling tool, and initiates the modeling tool to perform a 3D modeling algorithm for generating a final 3D model based on the graph structure. The final 3D model includes final 3D locations and geometries for the beams and joints and comprises a design solution that satisfies the design problem. The final 3D model can then be easily fabricated using standard beams and joints.

At least one technical advantage of the disclosed techniques relative to the prior art is that the disclosed techniques provide a parametric modeling tool that includes a visual programming interface through which design constraints can be defined that specify parameters that correspond to standard modular building components. For example, the design constraints can include parameters corresponding to a standard beam and/or standard joint. Further, the visual programming interface enables designers to easily define design constraints for design problems without having programming/coding expertise or knowledge. Another technical advantage is that, with the disclosed techniques, the design solutions generated for given design problems include geometric shapes that correspond to standard building components. Consequently, design solutions for architectural-scale structures can be readily fabricated using standard building components.

An additional technical advantage of the disclosed techniques relative to the prior art is that the parametric modeling tool is configured to integrate various functions of the parametric modeling tool and the topology optimization solver to automatically execute an overall design workflow to generate a design solution for a given design problem. In this regard, the parametric modeling tool executes a design workflow script that causes the parametric modeling tool and a topology optimization solver to interact in a collaborative manner to execute the design workflow. Notably, the design workflow script is configured to automatically cause multiple iterations of the design workflow to be executed. More specifically, for each iteration, the design workflow script automatically modifies the design problem and causes the design workflow to be re-executed based on the modified design problem. In this manner, the parametric modeling tool integrates functions of the parametric modeling tool and the topology optimization solver to automatically execute iterations of an overall design workflow to generate multiple design solutions for multiple design problems, thus allowing a designer to fully explore the overall design space. An additional technical advantage of the disclosed techniques relative to the prior art is that the disclosed techniques can be used to combine structural goals and constraints for architecture with non-structural goals and constraints for architecture, such as maximizing daylight, maximizing usable floor area, minimizing construction cost, reducing embodied carbon (for example, by reducing the amount of material used or by changing the material type, such as from aluminum to wood), and the like. These technical advantages provide one or more technological advancements over prior art approaches.

Aspects of the subject matter described herein are set out in the following numbered clauses.

1. In some embodiments, a computer-implemented method for generating a design for an architectural structure, the method comprising: receiving a design problem; automatically executing a design workflow by: generating a design problem specification based on the design problem; generating an optimized mesh geometry based on the design problem specification; generating a graph structure based on the optimized mesh geometry; and generating a three-dimensional (3D) model based on the graph structure.

2. The computer-implemented method of clause 1, wherein the 3D model comprises a design solution that satisfies the design problem.

3. The computer-implemented method of any of clauses 1-2, further comprising: automatically modifying the design problem to generate a modified design problem; automatically executing the design workflow based on the modified design problem to generate a modified design solution that satisfies the modified design problem.

4. The computer-implemented method of any of clauses 1-3, further comprising: receiving a set of iteration parameters that specifies a number of iterations of the design workflow; and automatically executing the design workflow a number of times commensurate with the number of iterations to generate a plurality of design solutions for a plurality of design problems.

5. The computer-implemented method of any of clauses 1-4, wherein the 3D model comprises a set of modular components that include a plurality of joints interconnected by a plurality of beams.

6. The computer-implemented method of any of clauses 1-5, wherein the plurality of joints satisfies a set of joint parameters specified in the design problem, and the plurality of beams satisfies a set of beam parameters specified in the design problem.

7. The computer-implemented method of any of clauses 1-6, wherein the design problem is received via a visual programming interface associated with the modeling tool engine.

8. The computer-implemented method of any of clauses 1-7, wherein the design problem includes a set of beam parameters specifying one or more dimensions of a beam component.

9. The computer-implemented method of any of clauses 1-8, wherein the set of beam parameters includes a beam thickness parameter that specifies a thickness of the beam component.

10. The computer-implemented method of any of clauses 1-9, wherein the set of beam parameters includes a beam width parameter that specifies a width of the beam component.

11. In some embodiments, one or more non-transitory computer-readable media storing instructions that, when executed by one or more processors, cause the one or more processors to generate a design for an architectural structure by performing the steps of: receiving a design problem; automatically executing a design workflow by: generating a design problem specification based on the design problem; generating an optimized mesh geometry based on the design problem specification; generating a graph structure based on the optimized mesh geometry; and generating a three-dimensional (3D) model based on the graph structure.

12. The one or more non-transitory computer-readable media of clause 11, further comprising: automatically modifying the design problem to generate a modified design problem; automatically executing the design workflow based on the modified design problem to generate a modified design solution that satisfies the modified design problem

13. The one or more non-transitory computer-readable media of any of clauses 11-12, wherein the design problem includes a set of beam parameters specifying one or more dimensions of a beam component.

14. The one or more non-transitory computer-readable media of any of clauses 11-13, wherein the set of beam parameters includes a beam thickness parameter that specifies a thickness of the beam component.

15. The one or more non-transitory computer-readable media of any of clauses 11-14, wherein the set of beam parameters includes a beam width parameter that specifies a width of the beam component.

16. The one or more non-transitory computer-readable media of any of clauses 11-15, further comprising: receiving a set of iteration parameters that includes a number of iterations of the design workflow; and automatically executing the design workflow a number of times commensurate with the number of iterations to generate a plurality of design solutions for a plurality of design problems.

17. The one or more non-transitory computer-readable media of any of clauses 11-16, wherein the set of iteration parameters further includes a range of values for a first constraint and an adjustment amount for the first constraint that is applied in different iterations of the design workflow.

18. The one or more non-transitory computer-readable media of any of clauses 11-17, wherein the set of iteration parameters further includes a range of values for a beam thickness constraint and an adjustment amount for the beam thickness constraint that is applied in different iterations of the design workflow.

19. The one or more non-transitory computer-readable media of any of clauses 11-18, wherein the set of iteration parameters further includes a range of values for a beam width constraint and an adjustment amount for the beam width constraint that is applied in different iterations of the design workflow.

20. In some embodiments, a system for generating a design for an architectural structure, the system comprising: a memory storing instructions; and a processor coupled to the memory that executes the instructions to perform the steps of: receiving a design problem; automatically executing a design workflow by: generating a design problem specification based on the design problem; generating an optimized mesh geometry based on the design problem specification; generating a graph structure based on the optimized mesh geometry; and generating a three-dimensional (3D) model based on the graph structure.

Any and all combinations of any of the claim elements recited in any of the claims and/or any elements described in this application, in any fashion, fall within the contemplated scope of the embodiments and protection.

The descriptions of the various embodiments have been presented for purposes of illustration but are not intended to be exhaustive or limited to the embodiments disclosed. Many modifications and variations will be apparent to those of ordinary skill in the art without departing from the scope and spirit of the described embodiments. Aspects of the present embodiments can be embodied as a system, method, or computer program product. Accordingly, aspects of the present disclosure can take the form of an entirely hardware embodiment, an entirely software embodiment (including firmware, resident software, and micro-code, etc.) or an embodiment combining software and hardware aspects that can all generally be referred to herein as a “module,” a “system,” or a “computer.” In addition, any hardware and/or software technique, process, function, component, engine, module, or system described in the present disclosure can be implemented as a circuit or set of circuits. Furthermore, aspects of the present disclosure can take the form of a computer program product embodied in one or more computer readable media having computer readable program codec embodied thereon.

Any combination of one or more computer readable media can be utilized. Each computer readable medium can be a computer readable signal medium or a computer readable storage medium. A computer readable storage medium can be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory, a read-only memory, an erasable programmable read-only memory, a Flash memory, an optical fiber, a portable compact disc read-only memory, an optical storage device, a magnetic storage device, or any suitable combination of the foregoing. In the context of this document, a computer readable storage medium can be any tangible medium that can contain or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions can be provided to a processor of a general-purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors can be, without limitation, general purpose processors, special-purpose processors, application-specific processors, or field-programmable gate arrays.

The flowchart and block diagrams in the figures illustrate the architecture, functionality, and operation of possible implementations of systems, methods, and computer program products according to various embodiments of the present disclosure. In this regard, each block in the flowchart or block diagrams can represent a module, segment, or portion of code, which comprises one or more executable instructions for implementing the specified logical function(s). It should also be noted that, in some alternative implementations, the functions noted in the block can occur out of the order noted in the figures. For example, two blocks shown in succession can, in fact, be block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure can be devised without departing from the basic scope thereof, and the scope thereof is determined by the claims that follow.

What is claimed is:

1. A computer-implemented method for generating a design for an architectural structure, the method comprising:
receiving a design problem;
automatically executing a design workflow by:
generating a design problem specification based on the design problem;
generating an optimized mesh geometry based on the design problem specification;
generating a graph structure based on the optimized mesh geometry; and
generating a three-dimensional (3D) model based on the graph structure.

2. The computer-implemented method of claim 1, wherein the 3D model comprises a design solution that satisfies the design problem.

3. The computer-implemented method of claim 1, further comprising:
automatically modifying the design problem to generate a modified design problem;
automatically executing the design workflow based on the modified design problem to generate a modified design solution that satisfies the modified design problem.

4. The computer-implemented method of claim 1, further comprising:
receiving a set of iteration parameters that specifies a number of iterations of the design workflow; and
automatically executing the design workflow a number of times commensurate with the number of iterations to generate a plurality of design solutions for a plurality of design problems.

5. The computer-implemented method of claim 1, wherein the 3D model comprises a set of modular components that include a plurality of joints interconnected by a plurality of beams.

6. The computer-implemented method of claim 5, wherein the plurality of joints satisfies a set of joint parameters specified in the design problem, and the plurality of beams satisfies a set of beam parameters specified in the design problem.

7. The computer-implemented method of claim 1, wherein the design problem is received via a visual programming interface associated with the modeling tool engine.

8. The computer-implemented method of claim 1, wherein the design problem includes a set of beam parameters specifying one or more dimensions of a beam component.

9. The computer-implemented method of claim 8, wherein the set of beam parameters includes a beam thickness parameter that specifies a thickness of the beam component.

10. The computer-implemented method of claim 8, wherein the set of beam parameters includes a beam width parameter that specifies a width of the beam component.

11. One or more non-transitory computer-readable media storing instructions that, when executed by one or more processors, cause the one or more processors to generate a design for an architectural structure by performing the steps of:
receiving a design problem;
automatically executing a design workflow by:
generating a design problem specification based on the design problem;
generating an optimized mesh geometry based on the design problem specification;
generating a graph structure based on the optimized mesh geometry; and
generating a three-dimensional (3D) model based on the graph structure.

12. The one or more non-transitory computer-readable media of claim 11, further comprising:
automatically modifying the design problem to generate a modified design problem;
automatically executing the design workflow based on the modified design problem to generate a modified design solution that satisfies the modified design problem.

13. The one or more non-transitory computer-readable media of claim 11, wherein the design problem includes a set of beam parameters specifying one or more dimensions of a beam component.

14. The one or more non-transitory computer-readable media of claim 13, wherein the set of beam parameters includes a beam thickness parameter that specifies a thickness of the beam component.

15. The one or more non-transitory computer-readable media of claim 13, wherein the set of beam parameters includes a beam width parameter that specifies a width of the beam component.

16. The one or more non-transitory computer-readable media of claim 11, further comprising:
receiving a set of iteration parameters that includes a number of iterations of the design workflow; and
automatically executing the design workflow a number of times commensurate with the number of iterations to generate a plurality of design solutions for a plurality of design problems.

17. The one or more non-transitory computer-readable media of claim 16, wherein the set of iteration parameters further includes a range of values for a first constraint and an adjustment amount for the first constraint that is applied in different iterations of the design workflow.

18. The one or more non-transitory computer-readable media of claim 16, wherein the set of iteration parameters further includes a range of values for a beam thickness constraint and an adjustment amount for the beam thickness constraint that is applied in different iterations of the design workflow.

19. The one or more non-transitory computer-readable media of claim 16, wherein the set of iteration parameters further includes a range of values for a beam width constraint and an adjustment amount for the beam width constraint that is applied in different iterations of the design workflow.

20. A system for generating a design for an architectural structure, the system comprising:
a memory storing instructions; and
a processor coupled to the memory that executes the instructions to perform the steps of:
receiving a design problem;
automatically executing a design workflow by:
generating a design problem specification based on the design problem;
generating an optimized mesh geometry based on the design problem specification;
generating a graph structure based on the optimized mesh geometry; and
generating a three-dimensional (3D) model based on the graph structure.
